(19) United States
(12) Patent Application Publication
(10) Pub. No.: US 2007/0285176 A1
(43) Pub. Date: Dec. 13, 2007

(54) Phase-Slipping Phase-Locked Loop

(75) Inventor: Brian B. North, Los Gatos, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Leadis Technology, Inc., Sunnyvale, CA (US)

(21) Appl. No.: 11/688,826

(22) Filed: Mar. 20, 2007

Related U.S. Application Data
(60) Provisional application No. 60/784,638, filed on Mar. 21, 2006.

(51) Int. Cl. H03L 7/081

(52) U.S. Cl. 331/8; 331/1 A

(57) ABSTRACT

A phase-slipping phase-locked loop which generates an output signal whose frequency is a non-integer multiple of a reference frequency. The PLL has a first input for receiving a first binary value i which specifies an integer portion of the frequency multiplier, and a second input for receiving a second binary value f which specifies a fractional portion of the frequency multiplier. A multi-phase VCO has a plurality v of outputs on equal phase shifted spacing. The phase slipping is applied every i cycles, and the second binary value f specifies a phase slip stride, such that the frequency multiplier equals i+f/v.

### RELATED APPLICATION

The present application claims benefit under 35 USC 119(e) of U.S. provisional Application No. 60/784,638, filed on Mar. 21, 2006, entitled “Adaptive Biasing Based on Volume Control Setting,” the content of which is incorporated herein by reference in its entirety.

### BACKGROUND OF THE INVENTION

1. Technical Field of the Invention

This invention relates generally to phase-locked loops (PLLs), and more specifically to reduction of spurs in the output signals of a fractional-N PLL.

2. Background Art

A phase-locked loop is a closed-loop feedback control system that generates and outputs a signal in relation to the frequency and phase of an input reference signal.

FIG. 1 illustrates a typical, conventional PLL 10. The PLL consists of four basic elements: a phase/frequency detector, a loop filter, a voltage-controlled oscillator, and a feedback path which optionally includes a frequency divider. The frequency divider is commonly implemented as a count-to-N circuit, whose output is its input divided by a predetermined integer N. The PLL circuit responds to both the frequency and the phase of the input signal, automatically raising or lowering the frequency of the VCO until it is matched to the reference in both frequency and phase.

By replacing the simple divide-by-N counter with a programmable pulse-swallowing counter, it is possible to obtain fractional multiples of the reference frequency out of the PLL. These types of PLLs are commonly referred to as fractional-N PLLs.

Fractional-N PLLs or synthesizers allow improved resolution over the setting of the output frequency, as compared to standard PLL architectures, for a given phase/frequency detector comparison frequency. The improved resolution is obtained by time-division modulating the integer N-counter value such that the average resulting value can be a fractional. In a fractional-N PLL, the N-counter is generally controlled by a modulator (e.g. a sigma-delta modulator) to obtain the non-integer values for the overall feedback division ratio.

This method is very effective in providing improved resolution, but causes the phase of the feedback signal to the phase/frequency detector to be constantly varying, and therefore the phase/frequency detector is constantly outputting a relatively large correction signal to the loop filter of the PLL. This correction signal is filtered by the loop filter, but still causes unwanted artifacts to be injected into the loop. The end result is that the output frequency spectrum contains unwanted spurs.

What is needed, then, is an improved PLL which provides an alternative method of providing a fractional-N count, while providing a near constant correction signal to the phase/frequency detector, thereby minimizing any potential spurs in the output.

### BRIEF DESCRIPTION OF THE DRAWINGS

FIG. 1 shows a conventional PLL according to the prior art.

FIG. 2 shows a phase-slipping PLL according to one embodiment of this invention.

FIG. 3 shows one embodiment of phase selection logic such as may be used in the phase-slipping PLL of FIG. 2.

FIG. 4 shows another embodiment of phase selection logic such as may be used in the phase-slipping PLL of FIG. 2.

FIG. 5 shows a waveform chart of various signals in the phase-slipping PLL of FIG. 2, using a frequency division factor having an integer part equal to two and fractional part equal to one eighth.

FIG. 6 shows a waveform chart of various signals in the phase-slipping PLL of FIG. 2, using a frequency division factor having an integer part equal to two and a fractional part equal to six eighths.

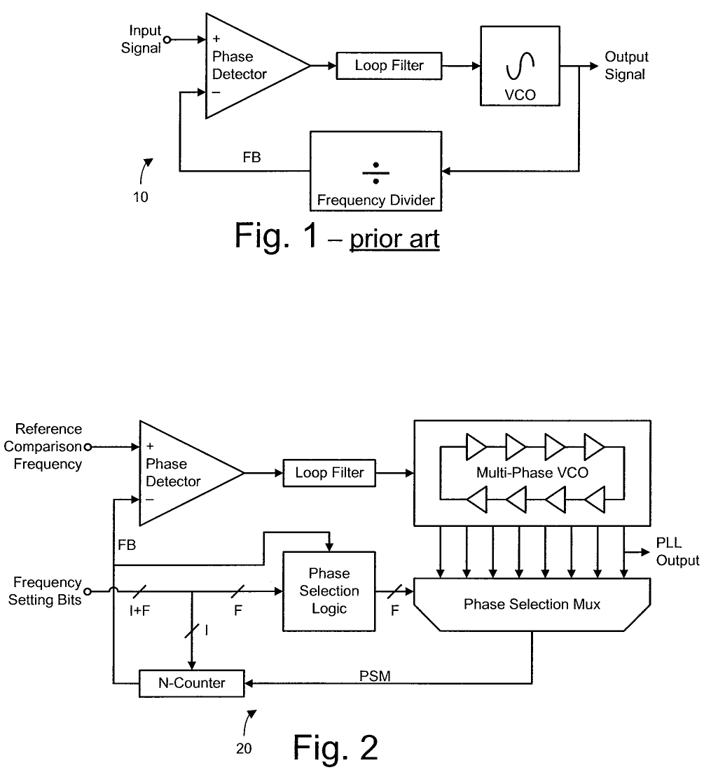

### DETAILED DESCRIPTION

The invention will be understood more fully from the detailed description given below and from the accompanying drawings of embodiments of the invention which, however, should not be taken to limit the invention to the specific embodiments described, but are for explanation and understanding only.

The present invention uses a novel phase slipping technique to provide an effective fractional-N counter value. The invention uses a multi-phase VCO and a phase selection logic circuit which supplies the input to the N counter.

FIG. 2 illustrates a phase-slipping PLL 20 according to one embodiment of this invention. The PLL includes a phase/frequency detector which receives the reference comparison frequency signal. The output of the phase/frequency detector is input to a loop filter which integrates and filters out the instantaneous correction signal from the phase detector (usually pulses) and provides the VCO with the correct average voltage to keep the loop both phase and frequency locked. The multi-phase VCO which outputs multiple signals of different phases and the same frequency. In the example shown, the VCO provides eight phases of output signal, each one eighth out of phase with each other such that they are evenly spaced in phasing.

A phase selection multiplexer receives the multiple outputs from the multi-phase VCO, and selects one of them in response to a control signal or value from phase selection logic circuitry. The output of the phase selection multiplexer is a feedback signal (PSM) which is input to an N-counter. The output of the N-counter is fed back to the other input of the phase/frequency detector. The phase selection logic operates according to a frequency setting signal or value (shown in this example as “frequency setting bits”) which are the input digital control setting. This can be a constant to set a fixed output frequency, or it can be the output of a sigma-delta modulator. The frequency setting signal or value is also fed to control the N-counter. Alternatively, the N-counter could be controlled by another output (not shown) of the phase selection logic.

In one embodiment, the frequency setting bits include I+F bits, of which I bits comprise a digital representation of the integer portion of the frequency multiplication factor, and F bits comprise a digital representation of the fractional portion of the frequency multiplication factor. Advantageously, F=log 2(V) where V is the number of phases provided by the VCO. In the example given, in which there are eight phases of output provided by the VCO, F=log 2(8)=3. The frequency setting word may, for example, be the binary value 00010011 in which the high order I bits 00010 specify the integer portion (i) (two in this example), and the low order F bits 011 specify the fractional portion (i) (three eighths in this example). The fractional portion f specifies the numerator of a fraction whose denominator is the number of phases provided by the VCO.

In operation, the phase selection logic provides the N-counter input with a different output phase of the VCO at each comparison frequency event of the phase/frequency detector. After every cycle of the reference frequency signal, the phase selection mux jumps by stride F to a next one of the VCO phase outputs, wrapping modulo V as necessary.

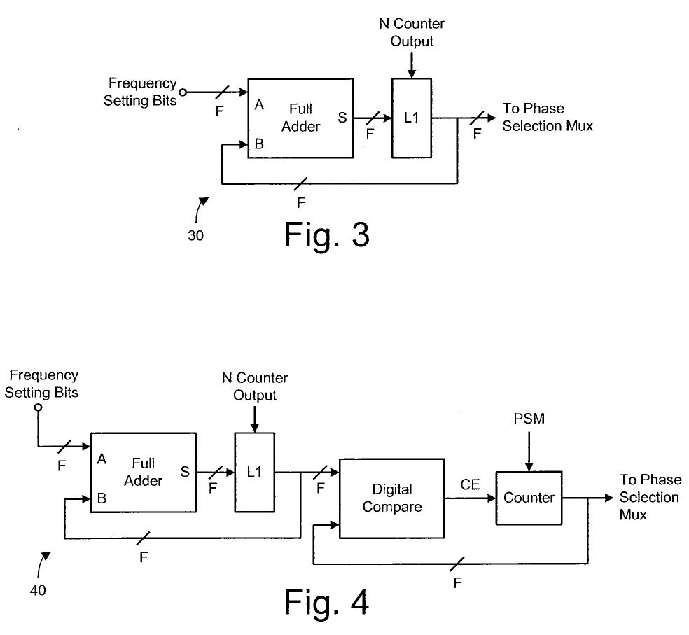

FIG. 3 illustrates one embodiment of the phase selection logic circuitry which may be used in the phase-shifting PLL of FIG. 2. The phase selection logic includes a two-input full adder which receives as its first input the F fractional bit value. The sum output of the adder input to a latch which is clocked by the output of the N-counter. The output of the latch is fed back to the second input of the adder, and also drives the phase selection mux. The adder implemented to discard any carry, and to wrap to the residue value when it passes the number V of the VCO phase outputs. For example, if F=3 and V=8, PSM might first transmit VCO phase 1, then phase 4, then phase 7, the phase 2, then phase 5, and so on.

FIG. 4 illustrates another embodiment of the phase selection logic circuit which may be used in the phase-shifting PLL of FIG. 2. It includes the circuitry of FIG. 3, and adds a digital comparator which receives the output of the latch, a counter which receives the output of the digital comparator and whose output drives the phase selection mux. The output of the counter is fed back to a second input of the digital comparator. The digital comparator block and counter act to moderate—that is, to spread out over time—the size of the phase step called for by L1. Instead of one large phase step being seen at PSM, the phase adjustment is spread out over numerous smaller steps, each of which is only the size of the difference between two adjacent VCO phase taps. For example, if the output of L1 were to jump from 1 to 4, the output of the counter would increment from 1 through 4 in single steps separated in time by the period of PSM.

In either implementation, the phase selection logic may be represented as an accumulator which adds the required number of phase slip steps per comparison cycle. If the accumulator is implemented as a full-adder or an up-down counter, then the circuit can be made to advance (forward) or retire (backward) a number of phase steps per comparison cycle, thereby allowing both a positive and a negative fractional frequency difference between the PLL output and the FB signal feedback to the input of the N-counter. If more than one phase step slip is required, then the steps can be combined to make a larger phase step or implemented sequentially, assuming the minimum N-counter value is longer than the maximum size of required phase steps to implement in one comparison cycle.

In a basic implementation, a modulator such as a sigma-delta modulator is not required, simplifying the digital circuitry required, and minimizing digital noise injection into the PLL.

The bits used to control the amount of phase slipping applied for every comparison event of the phase/frequency detector could themselves be modulated (along with some or all of the N-counter control bits) to further increase the amount of output frequency resolution available through a conventional modulation scheme, albeit at the expense of some possible increase in spur energy.

In some embodiments, it is preferable to do the phase slipping in a sequential manner, because making the phase jump in one big step can cause the input pulse to the N-counter to become very narrow, which can create performance demands of its own and may even cause extra current consumption. For low N-count values, it is desirable to slip on every edge of the VCO output, thereby allowing two phase slips per VCO period.

Although the phase tap for the N-counter input is altered, because the phase tap for the output of the VCO is not altered, the output signal does not become corrupted by the phase slipping activity.

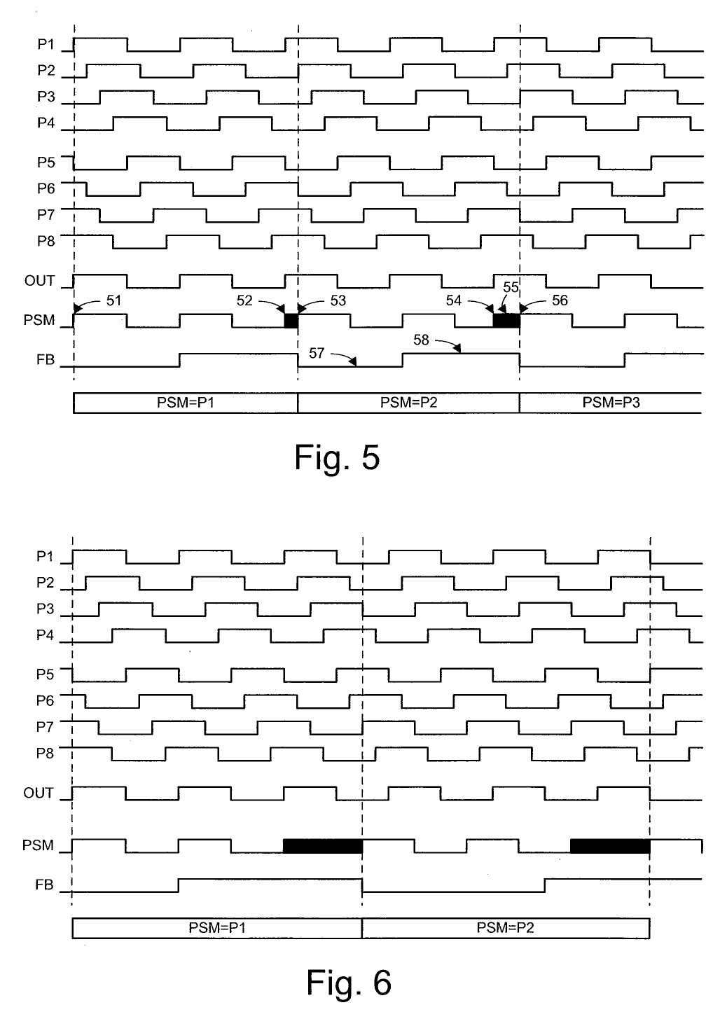

FIG. 5 shows sample waveforms for an 8-phase VCO slipping one phase element at a time. For ease of illustration, the indicated N-counter value (the integer portion of the frequency multiplication factor) is two in this example, as shown by the phase slip occurring every second PSM waveform event. In practice, the N-counter value would usually be much larger. The value two enables more than one slip to be shown within a small enough number of clock cycles to fit on a single sheet.

The method effectively provides the N-counter input with a composite waveform comprising periods of the same frequency as the PLL output (i.e. the VCO frequency), and one or more periods of a fractionally different frequency due to the addition (or subtraction) of a phase step. The number of phase slips per comparison frequency event of the phase/frequency detector is kept constant. Hence, the output frequency of the N-counter is a constant frequency and therefore, ideally, no spurs will be created even though the VCO output frequency is not an integer multiple of the reference comparison frequency. A greater fractional difference frequency can be obtained by slipping more than one phase element at every phase/frequency comparison event.

Referring also to FIG. 2, beginning at the time marked 51, the PSM signal tracks the PI phase signal from the VCO. Two PSM cycles later (as determined by the I value being two), at time 52 the phase selection logic causes the phase selection mux to jump one (as determined by the F value being one) VCO phase signal later, and the PSM signal begins tracking P2. At time 53, P2 goes high and consequently so does PSM. Time 54 is where PSM would have gone high if it were still tracking P1, and time 55 is where PSM would have gone high if it were still tracking P2. But at time 55, the phase selection logic causes the phase selection mux to jump one more VCO phase, and PSM begins tracking P3. At time 56, P3 goes high and consequently so does PSM. The FB feedback signal from the N-counter (of FIG. 2) to the second input of the phase detector tracks PSM in phase, and goes high every two (i) rising edges of PSM.

The low pulses of FB such as low pulse 57 are I times as long as a half cycle of any one of the VCO phase signals (such as P1). The high pulses of FB such as high pulse 58 are I+(F/V) times as long as a half cycle of any one of the VCO phase signals. In this example, 57 two times a P1 half cycle, and 58 is 2+⅛ times a P1 half cycle. The blocks marked “PSM=P1” and “PSM=P2” etc. denote the various full cycles of FB.

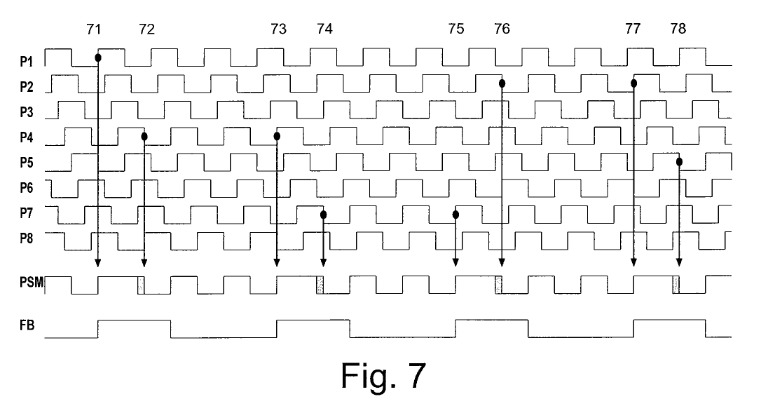

FIG. 6 illustrates phase shifting the system of FIG. 2 by I=2 and F=6, or in other words applying a 2+ 6/8 frequency multiplier to the reference frequency. If the reference comparison frequency input=10 MHz, I=2, F=6, and V=8, the output frequency will be 10 MHz*2+ 6/8=27.5 MHz, and the frequency of PSM will be 10 MHz*2=20 MHz. PSM is made to be reference frequency* 6/8=750 kHz slower than the output, by operation of the phase slipping mechanism which in effect slips PSM backward versus the output.

The technique of this invention is by nature spur-free and, all else being equal, would produce a pure carrier tone. In conventional fractional-N synthesis, in which the feedback divider is alternated between N and N+1 by a fixed pattern, by dithering, or by noise-shaping, the signal alternation by its very nature reduces the spectral purity of the resulting carrier, even if it's low and distributed rather than hobbled into discrete spurs.

FIG. 7 illustrates phase shifting the system of FIG. 2 by I=3, F=3, and V=8. This shows the mux extending individual positive PSM pulses based on FB events with those parameters. Note that each phase adjustment comes as a result of an FB positive edge in this embodiment.

After an initial point 71 in time on the (arbitrarily selected for illustration purposes to be the) first phase signal P1, the stride progresses by F=3 to the fourth phase signal P4 and that half cycle of PSM is extended such that its falling edge coincides with the next falling edge of P4 at point 72 in time. Then, after F=3 rising edges of P4 at time 73, the stride advances to select P7 as the next triggering signal, and that half cycle of PSM is extended such that its falling edge coincides with the next falling edge of P7 at time 74. Then, after F=3 rising edges of P7 at time 75, the stride advances to select P2, and PSM is extended to fall with P2 at time 76. Then, after F=3 rising edges of P2 at time 77, the stride advances to P5, and PSM is extended to fall with P5 at time 78.

### CONCLUSION

When one component is said to be “adjacent” another component, it should not be interpreted to mean that there is absolutely nothing between the two components, only that they are in the order indicated.

The various features illustrated in the figures may be combined in many ways, and should not be interpreted as though limited to the specific embodiments in which they were explained and shown.

Those skilled in the art, having the benefit of this disclosure, will appreciate that many other variations from the foregoing description and drawings may be made within the scope of the present invention. Indeed, the invention is not limited to the details described above. Rather, it is the following claims including any amendments thereto that define the scope of the invention.

What is claimed is:

1. A phase-slipping phase-locked loop comprising:
(a) a phase detector having,
a first input for receiving a reference comparison frequency signal,
a second input, and
an output;
(b) a multi-phase voltage-controlled oscillator having,
an input coupled to the output of the phase detector, and
a plurality of outputs each providing a respective, uniquely phase shifted output signal;
(c) a phase selection multiplexer having,
a plurality of inputs each coupled to a respective one of the outputs of the multi-phase voltage-controlled oscillator,
a selection control input, and
an output;
(d) an N-counter having,
an input coupled to the output of the phase selection multiplexer, and
an output coupled to the second input of the phase detector; and
(e) phase selection logic having,
an input for receiving a fractional phase shift value,
circuitry for generating a VCO phase selection value, and
an output coupled to provide the VCO phase selection value to the selection control input of the phase selection multiplexer.

2. The phase-slipping phase-locked loop of claim 1 wherein the phase selection logic comprises:
(1) a full adder having,
a first input for receiving the fractional phase shift value,
a second input, and
an output; and
(2) a latch having,
an input coupled to the output of the full adder,
a clock input coupled to the output of the N-counter, and
an output coupled to the selection control input of the phase selection multiplexer.

3. The phase-slipping phase-locked loop of claim 1 wherein the phase selection logic comprises:
(1) a full adder having,
a first input for receiving the fractional phase shift value,
a second input, and
an output;
(2) a latch having,
an input coupled to the output of the full adder,
a clock input coupled to the output of the N-counter, and
an output;
(3) a digital comparator having,
a first input coupled to the output of the latch,
a second input, and
an output; and
(4) a counter having,
an input coupled to the output of the digital comparator,
a clock input coupled to the output of the phase selection multiplexer, and
an output coupled to the selection control input of the phase selection multiplexer and to the second input of the digital comparator.

4. The phase-slipping phase-locked loop of claim 1 wherein the N-counter further comprises:
a control value input for receiving an integer frequency multiplier value.

5. The phase-slipping phase-locked loop of claim 1 further comprising:
(f) a loop filter disposed between the output of the phase comparator and the input of the VCO.

6. The phase-slipping phase-locked loop of claim 1 wherein:
the uniquely phase shifted output signals provided by the plurality of outputs of the multi-phase VCO are substantially equally spaced in phase.

7. A PLL for use with a reference comparison frequency signal, the PLL comprising:
a phase comparator for receiving the reference comparison frequency signal;
a loop filter coupled to the phase comparator;
a multi-phase VCO coupled to the loop filter;
a phase selection multiplexer coupled to the VCO; and
means for sequentially coupling a series of phase outputs of the VCO as feedback to the phase comparator;
whereby the PLL is capable of generating an output signal which is a non-integer multiple of the reference comparison frequency signal.

8. The PLL of claim 7 wherein:
the means for sequentially coupling includes an input for receiving a value which specifies a non-integer portion of the multiple.

9. The PLL of claim 8 wherein:
the means for sequentially coupling includes an input for receiving a value which specifies an integer portion of the multiple.

10. A method of operating a phase-slipping PLL to generate an output signal as a function of a reference comparison frequency signal, the method comprising:
receiving the reference comparison frequency signal;
comparing the reference comparison frequency signal to a feedback signal to generate a control signal;
synchronizing an oscillator in response to the control signal;
generating a plurality of phase shifted outputs of the oscillator, wherein the plurality of phase shifted outputs are substantially equally spaced in phase relationship;
periodically selecting a next one of the phase shifted outputs as a clock signal;
operating an N-counter in response to the clock signal; and
providing an output of the N-counter as the feedback signal;
thereby imparting to a selected one of the phase shifted outputs a non-integer frequency multiplier factor with respect to the reference comparison frequency signal.

11. The method of claim 10 wherein:
the plurality of phase shifted outputs includes V phase shifted outputs, wherein V is a positive integer greater than 2;
the method further comprises receiving a fractional value N which specifies a stride number according to which the next one of the phase shifted outputs is selected as the clock signal;
whereby the non-integer frequency multiplier factor comprises N/V.

12. The method of claim 11 wherein:
the period of the periodic selection determines an integer portion of the frequency multiplier factor.

13. The method of claim 12 further comprising:
receiving an integer value M which specifies the period;
whereby the frequency multiplier factor equals M+N/V.
